(19) United States
(12) Patent Application Publication
(10) Pub. No.: US 2025/0385103 A1
(43) Pub. Date: Dec. 18, 2025

(54) Semiconductor Device and Method of Making Using Microwave Soldering

(71) Applicant: JCET STATS ChipPAC Korea Limited, Incheon (KR)

(72) Inventors: Yeojun Yun, Incheon (KR); SeungHyun Lee, Incheon (KR); HeeSoo Lee, Incheon (KR)

(73) Assignee: JCET STATS ChipPAC Korea Limited, Incheon (KR)

(21) Appl. No.: 18/740,525

(22) Filed: Jun. 12, 2024

(51) Int. Cl. H01L 21/48; B23K 1/00; B23K 1/005; B23K 1/20; B23K 101/40; H01L 23/31; H01L 23/498

(52) U.S. Cl. CPC H01L 21/4853; B23K 1/0016; B23K 1/005; B23K 1/203; H01L 23/3128; H01L 23/49816; B23K 2101/40

(57) ABSTRACT

A semiconductor device has a semiconductor package and a flux disposed on the semiconductor package. A solder ball is disposed on the flux. The solder ball is reflowed using microwave energy. The microwave energy is applied until a temperature of the flux reaches between 200 and 220° C. The flux and solder ball both include polarized molecules. The substrate is devoid of polarized molecules.

### FIELD OF THE INVENTION

The present invention relates in general to semiconductor devices and, more particularly, to a semiconductor device and method of making using microwave soldering.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. At the same time, more and more complex semiconductor devices are demanded by device manufacturers. As devices become smaller, so do substrates and the other constituent parts of the device. Electrical interconnects become smaller and finer pitched. Making devices smaller increases their susceptibility to warpage during the manufacturing process. More advanced packaging techniques are constantly needed to control warpage and enable ever-smaller semiconductor packages.

### BRIEF DESCRIPTION OF THE DRAWINGS

FIGS. 1a-1c illustrate a semiconductor wafer with a plurality of semiconductor die separated by a saw street;

FIGS. 2a-2k illustrate forming a semiconductor package using microwaves for solder ball reflow;

FIG. 3 illustrates a multiple power module embodiment; and

FIGS. 4a and 4b illustrate an electronic device with the semiconductor package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The terms “semiconductor die” and “die” as used herein are synonymous and refer to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

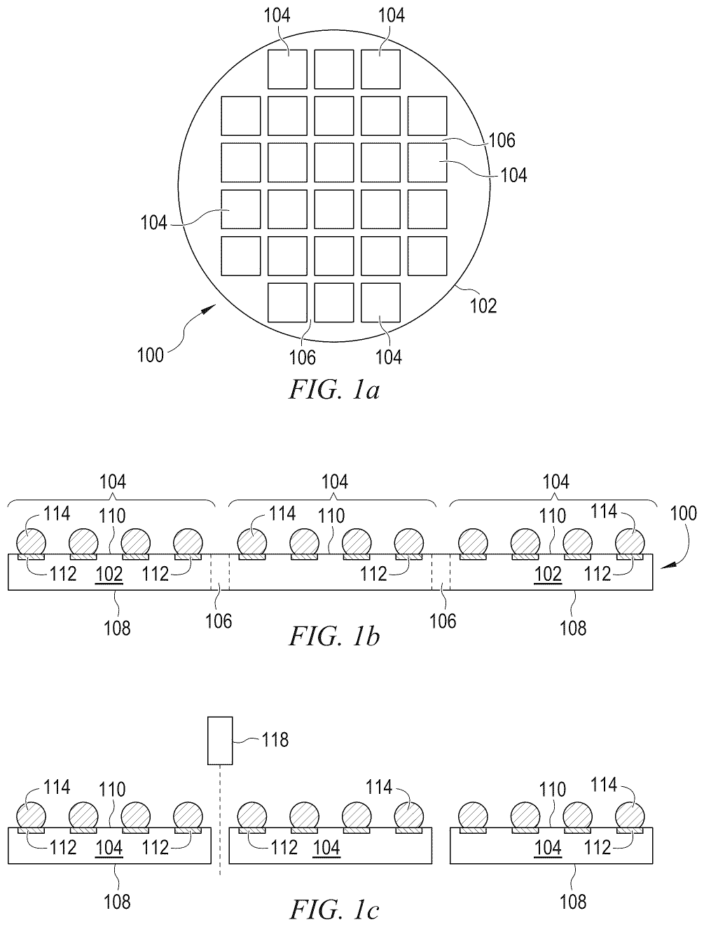

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under-bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

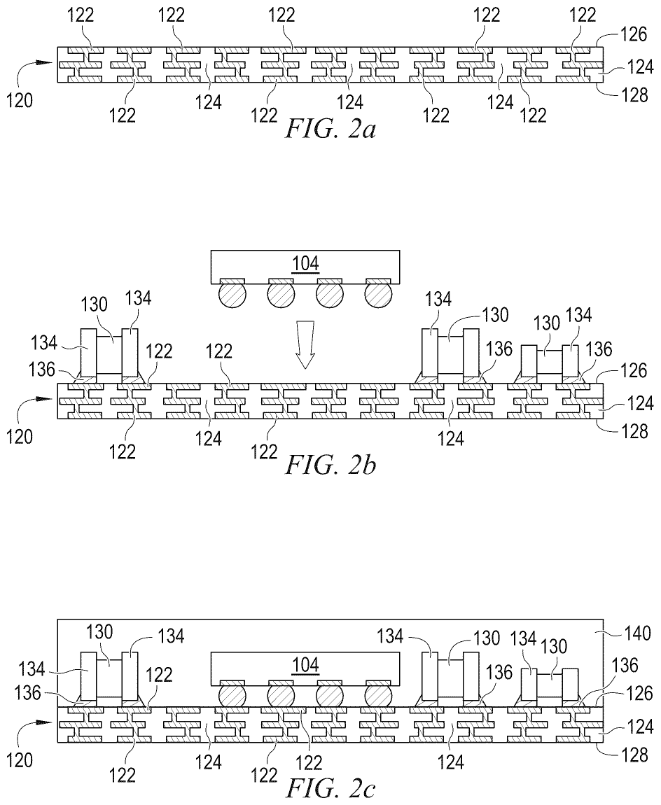

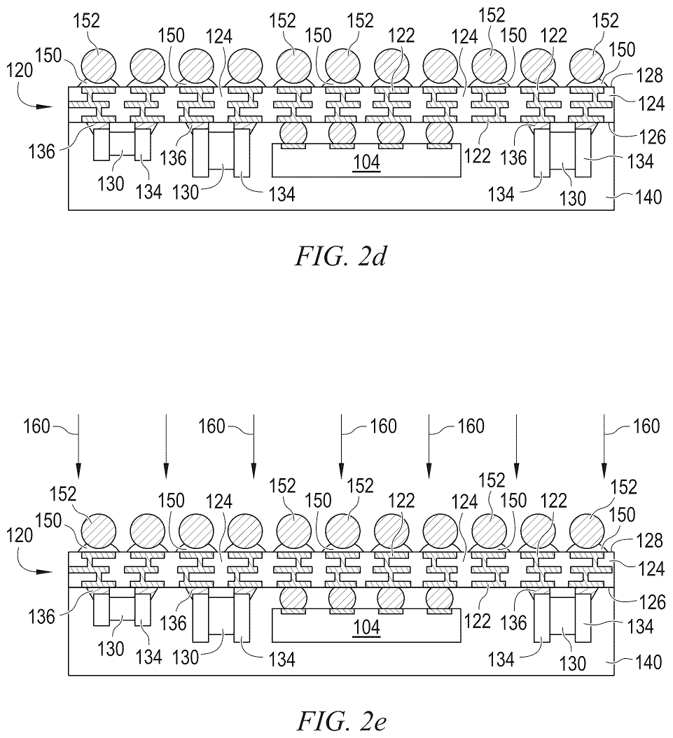

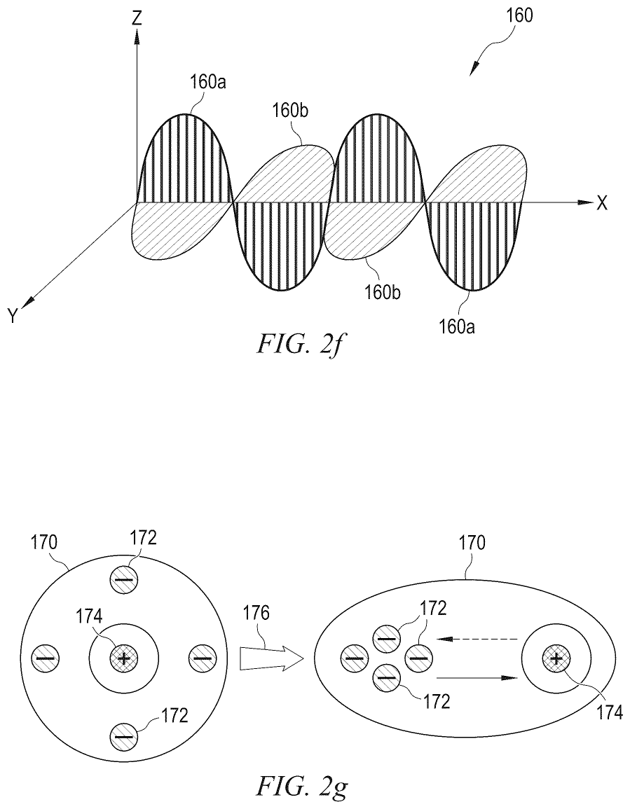

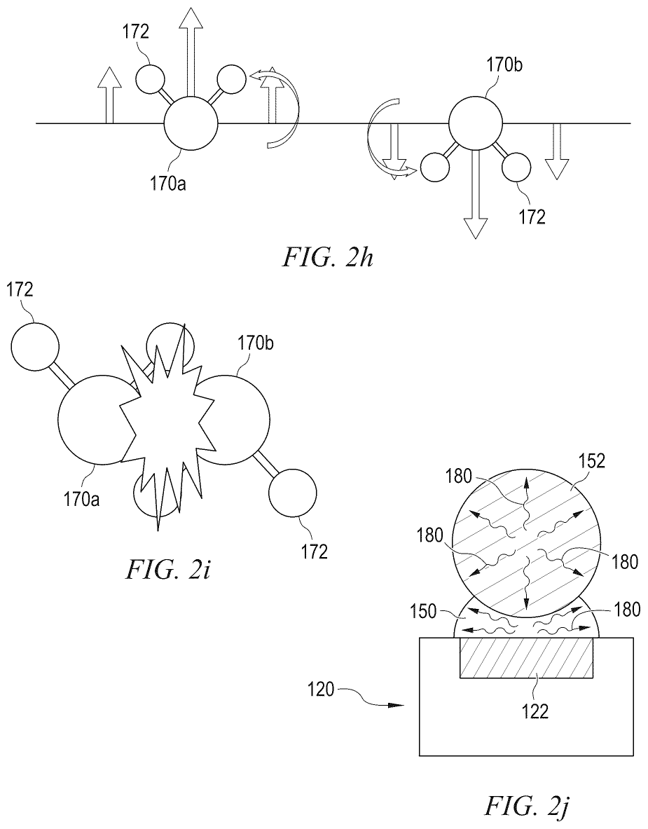

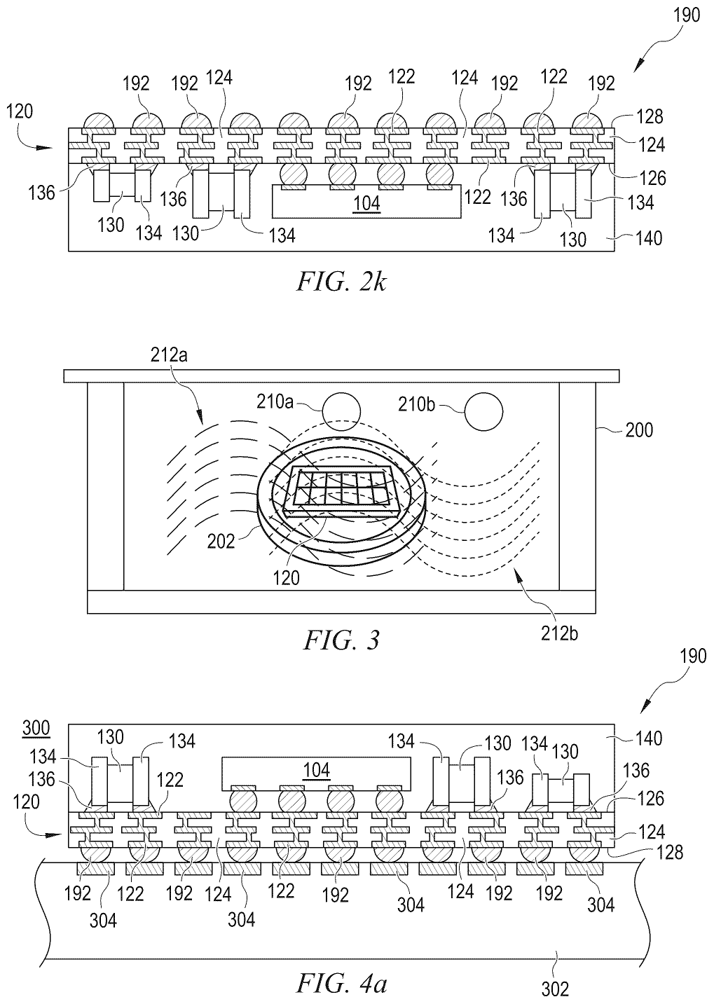

FIGS. 2a-2k illustrate a method of making a semiconductor package with microwaves used for solder bump reflow. FIG. 2a shows a package substrate 120. Substrate 120 is a multi-layered interconnect substrate including conductive layers 122 and insulating layers 124. While only a single substrate 120 suitable to form a single semiconductor package is shown, hundreds or thousands of units are commonly manufactured on, and processed as part of, a single substrate before being singulated from each other, using the same steps described herein performed en masse. A separate substrate 120 could also be used for each package being manufactured, the substrate being singulated before the steps shown hereafter and a plurality of individual substrates being placed on a common carrier for processing.

Conductive layers 122 can be one or more layers of Al, Cu, Sn, Ni, Au, Ag, or other suitable electrically conductive material. Conductive layers 122 can be formed using PVD, CVD, electrolytic plating, electroless plating, or other suitable metal deposition process. Conductive layers 122 provide horizontal electrical interconnect across substrate 120 and vertical electrical interconnect between top surface 126 and bottom surface 128. Portions of conductive layers 122 can be electrically common or electrically isolated depending on the design and function of the package being formed.

Insulating layers 124 contain one or more layers of SiO2, Si3N4, SiON, Ta2O5, Al2O3, solder resist, PI, BCB, PBO, and other material having similar insulating and structural properties. Insulating layers 124 can be formed using PVD, CVD, printing, lamination, spin coating, spray coating, sintering, thermal oxidation, or another suitable process. Insulating layers 124 provide isolation between conductive layers 122. Any number of conductive layers 122 and insulating layers 124 can be interleaved over each other to form substrate 120.

Any other suitable type of package substrate or leadframe is used for substrate 120 in other embodiments. For example, substrate 120 can be a laminate interposer, PCB, wafer-form, strip interposer, leadframe, or another suitable substrate. Substrate 120 may include one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics. Substrate 120 can also be a multi-layer flexible laminate, ceramic, copper clad laminate, glass, or semiconductor wafer including an active surface containing one or more transistors, diodes, and other circuit elements to implement analog circuits or digital circuits.

Any desired electrical components to implement the electrical functionality of the semiconductor package being formed are mounted on substrate 120 in FIG. 2b, including semiconductor die 104 from FIG. 1c. Additional electrical components 130 are disposed on surface 126 of interconnect substrate 120 alongside semiconductor die 104 and electrically and mechanically connected to conductive layers 122. For example, electrical components 130 can be discrete electrical devices, such as a diode, transistor, resistor, capacitor, and inductor. Electrical components 130 can include other semiconductor die, semiconductor packages, surface mount devices, RF components, discrete electrical devices, and may include integrated passive devices (IPDs).

Semiconductor die 104 and electrical components 130 are positioned over substrate 120 using a pick and place operation. Electrical components 130 are brought into contact with conductive layer 122 on surface 126 of substrate 120. Terminals 134 of electrical components 130 electrically and mechanically connected to conductive layer 122 using solder or conductive paste 136. Semiconductor die 104 are electrically and mechanically connected to conductive layer 122 by reflowing bumps 114.

FIG. 2c illustrates semiconductor die 104 and electrical components 130 electrically and mechanically connected to conductive layers 122 of substrate 120. An encapsulant or molding compound 140 is deposited over and around semiconductor die 104, electrical components 130, and substrate 120 using a paste printing, compression molding, transfer molding, liquid encapsulant molding, vacuum lamination, spin coating, or other suitable applicator. Encapsulant 140 can be liquid or granular polymer composite material, such as epoxy resin, epoxy acrylate, or another suitable polymer, with or without a filler. Encapsulant 140 is non-conductive, provides structural support, and environmentally protects the semiconductor device from external elements and contaminants.

In FIG. 2d, flux 150 is dispensed onto contact pads of conductive layer 122 exposed on bottom surface 128 of substrate 120, followed by placing of solder balls 152 onto the flux. Flux 150 can be dispensed using a nozzle or any other suitable means. Flux 150 removes any oxidized metal from the exposed surfaces of conductive layer 122, seals out air thus preventing further oxidation, and improves the wetting characteristics of the solder bumps 152 when reflowed. Any suitable flux composition can be used.

Solder balls 152 can be any suitable solder composition, such as those described above for bumps 114. SAC305 is used in one embodiment. Solder balls 152 are placed onto contact pads of conductive layer 122 and held in place by flux 150 being a liquid or semi-liquid with sufficient viscosity. Solder balls 152 can be picked and placed individually or as a group, dropped into a stencil with an opening for each desired ball, or disposed using any other suitable ball drop method.

In FIG. 2e, solder balls 152 are reflowed by applying microwave energy 160 to surface 128 of substrate 120, including to bumps 152 and flux 150, using a microwave emitter or other suitable means. Microwave energy 160 can be referred to in a variety of ways, e.g., a microwave signal, micro waves, or microwave photons. No matter what the actual phenomenon is called, electromagnetic radiation of sufficient frequency and power to reflow solder balls 152 is targeted at surface 128.

FIG. 2f illustrates a schematic view of a single photon of microwave energy 160 travelling along the X axis from left-to-right. Microwave energy 160, being a form of electromagnetic radiation, includes an electrical component 160a and a magnetic component 160b. Electrical component 160a oscillates in the X-Z plane and magnetic component 160b oscillates in the X-Y plane. Microwave energy 160 can be applied at a frequency anywhere from 1 GHz to 1, 000 GHz. The frequency of microwave energy 160 can be changed during irradiation for reflow, e.g., using a variable-frequency microwave (VFM) system.

As microwave energy 160 passes through matter, e.g., solder balls 152 and flux 150, the electrical component 160a oscillating distorts the cloud of negatively charged electrons around positive atomic nuclei. FIG. 2g illustrates the distortion effect. On the left side of FIG. 2g is an atom 170 without microwave energy 160 applied. Electrons 172 are evenly distributed around each side of nucleus 174. On the right side of FIG. 2g, with microwave energy 160 applied as indicated by arrow 176, electrons 172 are all pushed to one side of nucleus 174 by the electrical field of electrical component 160a.

As electrical component 160a passes by and through atoms and molecules, the molecules are polarized in an oscillating fashion due to the electrical field oscillating as shown in FIG. 2f. FIG. 2h shows that atom 170 is polarized in two opposing directions depending on which part of electrical component 160a is disposed at or adjacent to that specific atom. Atom 170a has electrons 172 oriented upward in FIG. 2h because electrical component 160a has its electrical field polarized in that direction next to atom 170a. Atom 170b has electrons 172 oriented downward in FIG. 2h because electrical component 160a has its electrical field polarized in that direction next to atom 170b. Polarized molecules can be similarly rotated by microwave energy 160. Microwaves induce molecular rotation without destroying molecular bonds due to having a low energy per photon.

As nearby atoms or molecules continually oscillate in response to microwave energy 160, the atoms or molecules will periodically collide with each other as shown in FIG. 2i. Friction energy of colliding atoms or molecules converts to heat energy and is eventually sufficient to melt solder balls 152.

One advantage of solder reflow using microwave energy 160 comes from only polarized atoms and molecules being impacted. Flux 150 is typically the most polar material of everything shown in FIG. 2e, and therefore is heated most by microwave energy 160, while solder balls 152 are the second most polar material. Typical materials of substrate 120 are not polar and therefore the substrate is not affected by microwave energy 160. Warpage of substrate 120 during manufacturing is reduced by not directly heating the substrate.

A second advantage of solder reflow using microwave energy 160 comes from utilizing volumetric heating instead of convection heating as is typical in prior art oven reflow. Volumetric heating heats from the inside out, while convection heating heats from the outside in. FIG. 2j illustrates volumetric heating as arrows 180 emanating internally to the heated components, flux 150 and solder balls 152. Flux 150 has a higher density of arrows 180 because the flux is the most polar material, while solder balls 152 are less polar but still significantly so. With the application of microwave energy 160, flux 150 quickly rises to above the melting temperature of solder bumps 152. Volumetric heating enables efficient control of heat distribution. Substrate 120 has no arrows 180 because the substrate material is not significantly polar and is not subject to volumetric heating. Volumetric heating can also impact other organic materials composed of polar molecules such as underfill or epoxy-molding compound.

In one embodiment, an output power of the microwave generator for microwave energy between 160 and 1600 Watts. In other embodiments, dual microwave modules are used with each outputting between 500-1000 Watts. The process proceeds as follows in one specific embodiment. Variable Frequency Microwave (VFM) is used to change the frequency of microwave energy 160 from 5.65 GHz to 6.65 GHz over the course of reflow. The temperature of flux 150 rises linearly at approximately 3 degrees Celsius (° C.) per second. Microwave energy 160 is applied until a temperature of 200-220° C. is reached to melt solder balls 152. After heating, the temperature is maintained at a maximum for 30 seconds before cooling naturally. Temperature can be maintained by modulating application of microwave energy 160 or other suitable means. In practice, the temperature should be maintained at approximately the maximum and not necessarily exactly the maximum, e.g., within 2-3° C. of the maximum for 30 seconds.

FIG. 2k illustrates a completed package 190 after solder balls 152 have been reflowed with microwave energy 160. Flux 150 has evaporated or mixed with the melted solder of solder balls 152 to form bumps 192. Balls 152 are melted into bumps 192 without applying significant thermal energy to substrate 120, so the substrate is less susceptible to warpage than when convection heating is used. Microwave energy 160 is also a faster heating mechanism than oven heating. The reduced warpage allows for smaller packages and more complex package structures to be realized, e.g., package-on-package or system-in-package structures with thinner interposers, higher complexity, and more various components. In some embodiments, packages 190 are formed as a panel and singulated through encapsulant 140 and substrate 120 to separate the individual packages from each other.

FIG. 3 illustrates an embodiment utilizing a plurality of microwave emitters. Substrate 120 with a plurality of packages formed thereon is placed within a chamber 200 on a carrier 202. A first microwave emitter 210a is disposed directly over substrate 120 while a second emitter 210b is disposed outside a footprint of the substrate. Emitter 210a emits microwave energy 212a while emitter 210b emits microwave energy 212b. Microwave energy 210a and 210b overlap to both impact solder balls 152 together. The positions and angles of microwave emitters 210a and 210b are configurable to optimize solder reflow and thereby fully reflow all solder balls 152. Two emitters working together can warm up the entire footprint of substrate 120 at a much more uniform rate compared to a single emitter, which tends to reflow some solder balls first and then expand the area reflowed across the substrate footprint. Both emitters 210a and 210b typically emit the same microwave frequency, but different frequencies are used in other embodiments. Some embodiments utilize only a single emitter 210a or 210b, but using two emitters together improves performance.

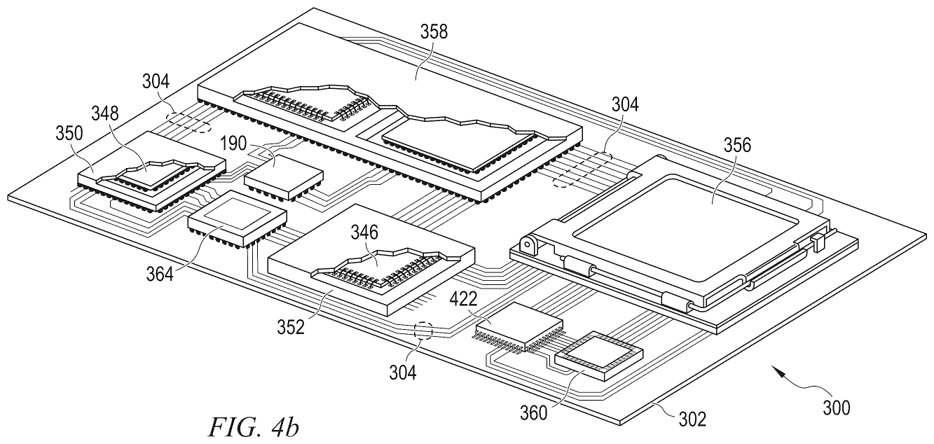

FIGS. 4a and 4b illustrate integrating the above-described semiconductor packages, e.g., semiconductor package 190, into a larger electronic device 300. FIG. 4a illustrates a partial cross-section of semiconductor package 190 mounted onto a printed circuit board (PCB) or other substrate 302 as part of electronic device 300. Solder bumps 192 are reflowed onto conductive layer 304 of PCB 302 to physically attach and electrically connect semiconductor package 190 to the PCB. In other embodiments, thermocompression or another suitable attachment and connection methods are used. In some embodiments, an adhesive or underfill layer is used between semiconductor package 190 and PCB 302. Semiconductor die 104 are electrically coupled to conductive layer 304 through substrate 120.

FIG. 4b illustrates electronic device 300 having a chip carrier substrate or PCB 302 with a plurality of semiconductor packages disposed on a surface of PCB 302, including semiconductor package 190. Electronic device 300 can have one type of semiconductor package, or multiple types of semiconductor packages, depending on the application. In other embodiments, semiconductor package 190 is incorporated as only one part of another larger semiconductor package, e.g., a system-in-package, before being incorporated into a larger electronic device 300.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICS, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 4b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor package;
disposing a flux on the semiconductor package;
disposing a solder ball on the flux; and
reflowing the solder ball using microwave energy.

2. The method of claim 1, further including applying the microwave energy until a temperature of the flux reaches between 200 and 220° C.

3. The method of claim 2, further including maintaining approximately the maximum temperature reached for 30 seconds.

4. The method of claim 1, further including forming the semiconductor package prior to reflowing the solder ball by,
providing a substrate;
disposing an electrical component over the substrate; and
depositing an encapsulant over the electrical component.

5. The method of claim 4, wherein the substrate is devoid of polarized molecules.

6. The method of claim 5, wherein the flux and solder ball both include polarized molecules.

7. A method of making a semiconductor device, comprising:
providing a substrate;
disposing a flux on the substrate;
disposing a solder ball on the flux; and
reflowing the solder ball using microwave energy.

8. The method of claim 7, further including applying the microwave energy until a temperature of the flux reaches between 200 and 220° C.

9. The method of claim 8, further including maintaining approximately the maximum temperature reached for 30 seconds.

10. The method of claim 7, further including,
disposing an electrical component over the substrate;
depositing an encapsulant over the electrical component; and
disposing the flux and solder ball over the substrate opposite the encapsulant.

11. The method of claim 7, wherein the substrate is devoid of polarized molecules.

12. The method of claim 11, wherein the flux and solder ball include polarized molecules.

13. The method of claim 7, wherein the substrate includes an insulating material and a conductive layer formed over the insulating material.

14. A method of making a semiconductor device, comprising:
providing a substrate;
disposing a solder ball over the substrate; and
reflowing the solder ball using microwave energy.

15. The method of claim 14, further including applying the microwave energy until a temperature of the solder ball reaches between 200 and 220° C.

16. The method of claim 15, further including maintaining approximately the maximum temperature reached for 30 seconds.

17. The method of claim 14, further including,
disposing an electrical component over the substrate;
depositing an encapsulant over the electrical component; and
disposing the solder ball over the substrate opposite the encapsulant.

18. The method of claim 14, wherein the substrate is devoid of polarized molecules.

19. The method of claim 18, wherein the solder ball includes polarized molecules.

20. The method of claim 14, wherein the solder ball includes polarized molecules.

21. A semiconductor device, comprising:
a substrate;
a solder ball disposed over the substrate; and
a microwave emitter disposed over the substrate.

22. The semiconductor device of claim 21, further including:
an electrical component disposed over the substrate opposite the solder ball; and
an encapsulant deposited over the electrical component and substrate.

23. The semiconductor device of claim 21, further including a flux disposed between the substrate and solder ball.

24. The semiconductor device of claim 21, wherein the substrate is devoid of polarized molecules.

25. The semiconductor device of claim 24, wherein the solder ball includes polarized molecules.
